(19) United States
(12) Patent Application Publication
(10) Pub. No.: US 2014/0052403 A1
(43) Pub. Date: Feb. 20, 2014

(54) TEST SYSTEM AND TEST METHOD THEREOF

(71) Applicant: WISTRON CORP., New Taipei City (TW)

(72) Inventor: Hao TANG, New Taipei City (TW)

(21) Appl. No.: 13/901,897

(22) Filed: May 24, 2013

(30) Foreign Application Priority Data
Aug. 15, 2012 (CN) 201210291581.X

(51) Int. Cl. G01R 31/317

(52) U.S. Cl. CPC G01R 31/31723
USPC 702/119

(57) ABSTRACT

An embodiment of a test system is provided. The system includes an electronic device to be tested and a network connection device. The electronic device to be tested includes a central processing unit (CPU) and a first universal serial bus (USB) interface. The network connection device includes a LAN module coupled to a remote server via a LAN port, and a second USB interface. When the second USB interface of the network connection device is coupled to the first USB interface of the electronic device to be tested, the CPU of the electronic device to be tested obtains a specific program from the remote server via the LAN port and the LAN module of the network connection device according to a preboot execution environment (PXE) code from the network connection device.

### CROSS REFERENCE TO RELATED APPLICATIONS

This Application claims priority of China Patent Application No. 201210291581.X, filed on Aug. 15, 2012, the entirety of which is incorporated by reference herein.

### BACKGROUND OF THE INVENTION

1. Field of the Invention

The invention relates to a test system, and more particularly to a test system for an electronic device that supports a Preboot Execution Environment (PXE).

2. Description of the Related Art

Hardware and software of computer products have to be tested before the products are sold to ensure product quality. Since manufacturers produce a large number of computer products with different features, a general, automated and highly efficient test system is needed.

At present, a general network test system has high efficiency and applied in many fields, and generally comprises a server and a test database. According to a design of a device under test (DUT), an operator can set up test files and test environment files into the server in advance for the DUT to download, so as to perform test operations to the DUT. In addition, the test database can provide related test parameters and collect test results of the DUT.

For the DUT of computer products, an operator must test the DUT in various operating systems, to ensure that the products can operate normally in different operating systems. In the network test system, the DUT needs to download a setup procedure module (known as Answer File) from the server via remote install technology, to thereby set up the testing operating system of the server.

At present, one remote install environment is a Preboot Execution Environment (PXE), which is usually used in a network test system. In general, a standard PXE program code is burnt/programmed in the Boot ROM of a network card or in the Basic Input/Output System (BIOS). When the computer is powered on, the BIOS is performed. If the computer is set to be booted from a PXE code, the BIOS will transfer the authority to the PXE code and then the PXE code is performed. When the PXE code obtains the authority, a network card is driven, so as to download the test operations from the server via the network.

### BRIEF SUMMARY OF THE INVENTION

A test system and a test method for an electronic device are provided. An embodiment of a test system is provided. The system comprises an electronic device to be tested and a network connection device. The electronic device to be tested comprises a central processing unit (CPU) and a first universal serial bus (USB) interface. The network connection device comprises a LAN module coupled to a remote server via a LAN port, and a second USB interface. When the second USB interface of the network connection device is coupled to the first USB interface of the electronic device to be tested, the CPU of the electronic device to be tested obtains a specific program from the remote server via the LAN port and the LAN module of the network connection device according to a preboot execution environment (PXE) code from the network connection device.

Furthermore, an embodiment of a test method for an electronic device is provided. It is detected whether a network connection device having a specific device descriptor is coupled to a universal serial bus (USB) interface of the electronic device during a power on self test (POST), wherein the network connection device comprises a LAN port coupled to a first remote server via a network line. A preboot execution environment (PXE) code is obtained from the network connection device via the USB interface. A specific program is provided from the first remote server via the LAN port of the network connection device according to the PXE code. A test operation or a preload operation is performed according to the specific program.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a test system according to an embodiment of the invention;

FIG. 2 shows the network connection device of FIG. 1 according to an embodiment of the invention; and

FIG. 3A and FIG. 3B show a test method for the electronic device of FIG. 1 according to an embodiment of the invention.

### DETAILED DESCRIPTION OF THE INVENTION

The following description is of the best-contemplated mode of carrying out the invention. This description is made for the purpose of illustrating the general principles of the invention and should not be taken in the limiting sense. The scope of the invention is best determined by reference to the appended claims.

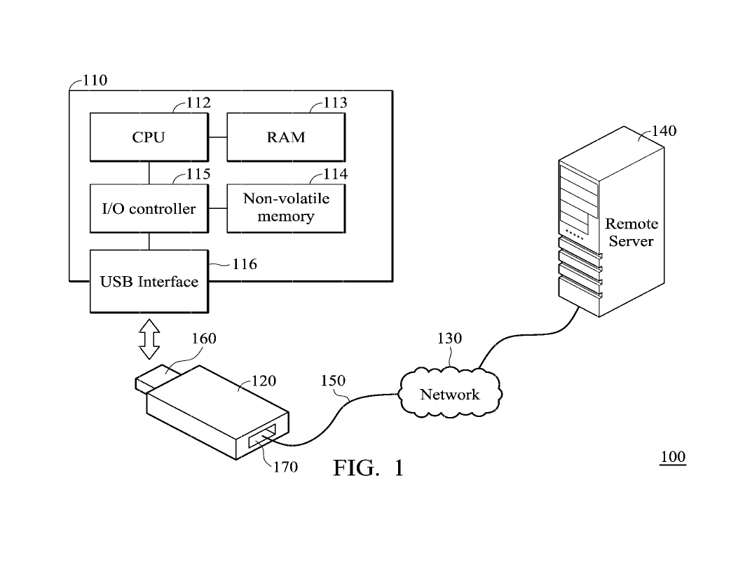

FIG. 1 shows a test system 100 according to an embodiment of the invention. The test system 100 comprises an electronic device 110 to be tested, a network connection device 120 and a remote server 140. The electronic device 110 comprises a Central Processing Unit (CPU) 112, a Random Access Memory (RAM) 113, a non-volatile memory 114, an input/output (I/O) controller 115 and a Universal Serial Bus (USB) interface 116, wherein the I/O controller 115 is coupled between the CPU 112, the non-volatile memory 114 and the USB interface 116. It is to be noted that the electronic device 110 is a notebook or a tablet computer without a LAN port (i.e. no LAN port is disposed on the electronic device 110), wherein the electronic device 110 is capable of supporting a remote install environment of a Preboot Execution Environment (PXE). In the embodiment, the network connection device 120 is a network card which is a USB dongle with a LAN port 170, wherein the network connection device 120 is coupled to the USB interface 116 of the electronic device 110 via a USB plug 160 thereof. Furthermore, the LAN port 170 of the network connection device 120 is coupled to the remote server 140 via a network line 150 and a network 130. Therefore, when the electronic device 110 is powered on, the CPU 112 of the electronic device 110 performs a boot procedure according to a Basic Input/Output System (BIOS) code stored in the non-volatile memory 114. Next, when the electronic device 110 detects that the network connection device 120 has been coupled to the USB interface 116 thereof, the CPU 112 enables the network functions of the network connection device 120 according to a PXE code stored in the network connection device 120, so as to download the test programs or preload programs of the electronic device 110 from the remote server 140 via the network line 150 and the network 130. The PXE code may be a PXE ROM code programmed in the network card of a conventional computer or a PXE unified extensible firmware interface (UEFI) driver.

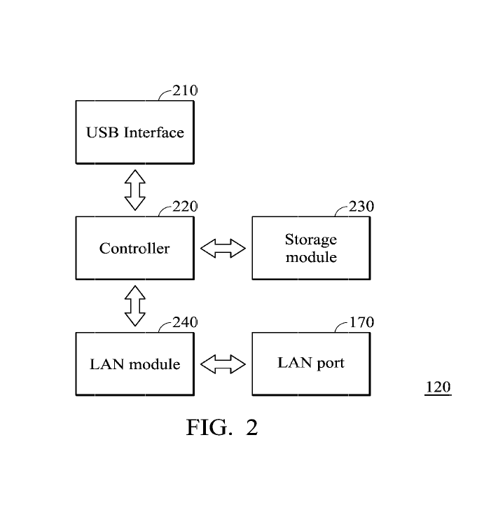

FIG. 2 shows the network connection device 120 of FIG. 1 according to an embodiment of the invention. The network connection device 120 comprises a USB interface 210, a controller 220, a storage module 230, a LAN module 240 and the LAN port 170. The controller 220 is used to control the USB interface 210, the storage module 230 and the LAN module 240. The storage module 230 may be a flash memory for storing the PXE code (e.g. the PXE ROM code or the PXE UEFI driver) and an Operation System (OS) (e.g. WinPE or Linus) that the electronic device 110 can support. Furthermore, the storage module 230 further stores a driver of the LAN module 240. In one embodiment, the PXE code (e.g. the PXE ROM code or the PXE UEFI driver) and the OS (e.g. WinPE or Linus) are stored in different segments of the storage module 230 for management. Referring to FIG. 1 and FIG. 2 together, the electronic device 110 performs a BIOS boot procedure after the electronic device 110 is powered on. Next, the electronic 110 reads the PXE code stored in the storage module 230 via the USB interface 116, the USB interface 210 and controller 220, and then the electronic 110 loads the PXE ROM code or the PXE UEFI driver according to the read PXE code. Next, the electronic device 110 perform a PXE boot procedure, so as to download the test programs or preload programs of the electronic device 110 from the remote server 140 via the network line 150 and the network 130.

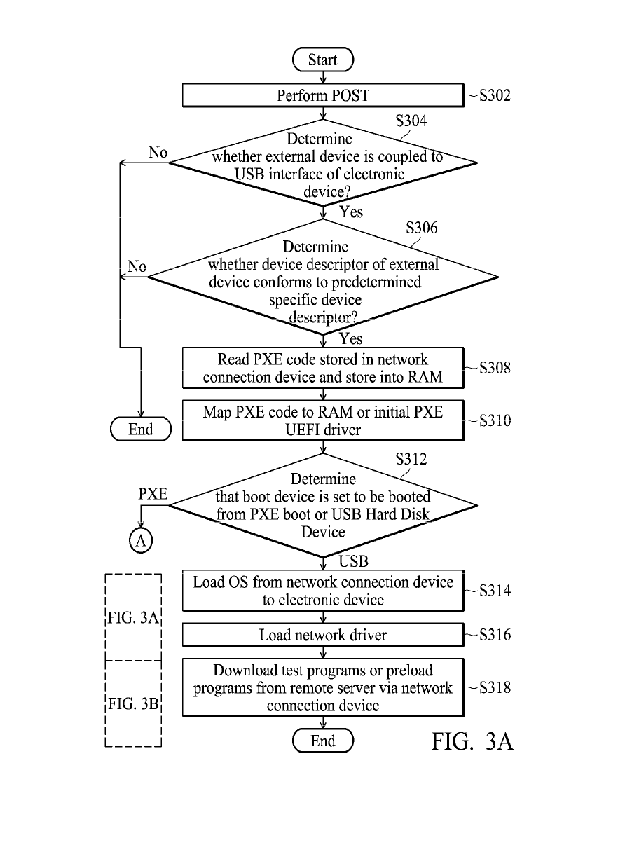

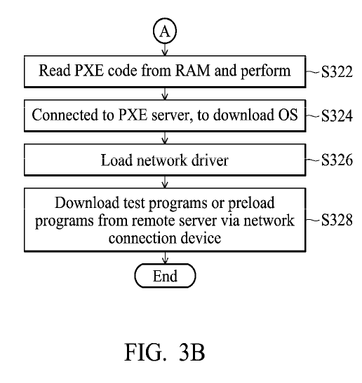

FIG. 3A and FIG. 3B show a test method for the electronic device 110 of FIG. 1 according to an embodiment of the invention. Referring to FIG. 1 and FIG. 3A together, first, in the BIOS boot procedure, the electronic device 110 performs a Power On Self Test (POST) (step S302). Next, in the Driver Execution Environment (DXE) phase, the CPU 112 of the electronic device 110 determines whether an external device is coupled to the USB interface 116 of the electronic device 110 (step S304). If no, the electronic device 110 continues to perform the POST. If the external device is coupled to the USB interface 116 of the electronic device 110, the CPU 112 further determines whether a device descriptor of the external device conforms to a predetermined specific device descriptor (step S306), For example, it is determined whether the external device is the network connection device 120 of FIG. 1. If no, the electronic device 110 continues to perform the POST. If the external device is the network connection device 120, the CPU 112 reads the PXE code (e.g. the PXE ROM code or the PXE UEFI driver) stored in the network connection device 120 via the USB interface 116, and stores the read PXE code into the RAM 113 (step S308). Next, in step S310, the CPU 112 maps the PXE code to an expansion area of the RAM 113 or initializes the PXE UEFI driver. Next, in step S312, in the Boot Device Select (DBS) phase, the CPU 112 determines that a boot device is set to be booted from a PXE boot or a USB Hard Disk Device (HDD) according to boot order information. When the boot device is set to be booted from the USB HDD, the CPU 112 loads the OS (e.g. WinPE or Linux) from the network connection device 120 to the electronic device 110 (step S314). Next, in step S316, the CPU 112 loads a network driver stored in the network connection device 120, to the OS, so as to enable the LAN module 240 of the network connection device 120 in FIG. 2. Next, in step S318, the CPU 112 is coupled to the remote server 140 via the network connection device 120, so as to download test programs or preload programs from the remote server 140 to a hard disk of the electronic device 110. Thus, test operations are performed for the electronic device 110.

Furthermore, referring to FIG. 1 and FIG. 3B together, when the boot device is set to be booted from the PXE boot, the CPU 112 reads the PXE ROM code or the PXE UEFI driver from the RAM 113 to perform (step S322). The CPU 112 initializes the LAN module 240 of the network connection device 120 according to the PXE ROM code or the PXE UEFI driver. Next, the CPU 112 is connected to a PXE server via the network connection device 120, so as to download the OS (e.g. WinPE or Linus) to the electronic device 110 (step S324). Next, in step S326, the CPU 112 loads the network driver stored in the network connection device 120, to the OS, so as to control the LAN module 240 of the network connection device 120 in FIG. 2. Next, in step S328, the CPU 112 is coupled to the remote server 140 via the network connection device 120, so as to download test programs or preload programs from the remote server 140 to a hard disk of the electronic device 110. Thus, test operations are performed for the electronic device 110.

Traditionally, a PXE code is stored in the BIOS code of an electronic device. Therefore, according to the embodiments, a BIOS code is decreased in size by storing a PXE code (e.g. a PXE ROM code or a PXE UEFI driver) into an external network connection device. Moreover, for mass production test, if the PXE code needs to be updated, only the PXE code of the network connection device is updated rather than the BIOS code of the electronic device. Thus, production efficiency is increased.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A test system, comprising:
an electronic device to be tested, comprising:
a central processing unit (CPU); and
a first universal serial bus (USB) interface; and
a network connection device, comprising:
a LAN module coupled to a remote server via a LAN port; and
a second USB interface,
wherein when the second USB interface of the network connection device is coupled to the first USB interface of the electronic device to be tested, the CPU of the electronic device to be tested obtains a specific program from the remote server via the LAN port and the LAN module of the network connection device according to a preboot execution environment (PXE) code from the network connection device.

2. The test system as claimed in claim 1, wherein the CPU of me electronic device to be tested performs a test operation or a preload operation according to the specific program.

3. The test system as claimed in claim 1, wherein the network connection device further comprises:
a storage module, storing the PXE code, wherein the PXE code comprises a PXE ROM code or a PXE unified extensible firmware interface (UEFI) driver.

4. The test system as claimed in claim 1, wherein when a power on self test (POST) is performed by the electronic device to be tested, the CPU of the electronic device to be tested further determines whether the second USB interface of the network connection device is coupled to the first USB interface of the electronic device to be tested.

5. The test system as claimed in claim 4, wherein when the CPU of the electronic device to be tested determines that the second USB interface of the network connection device is coupled to the first USB interface of the electronic device to be tested, the electronic device to be tested loads a driver corresponding to the LAN module of the network connection device, to an operating system (OS).

6. The test system as claimed in claim 5, wherein the OS is preloaded from the storage module of the network connection device to the electronic device to be tested.

7. The test system as claimed in claim 1, wherein no LAN port is disposed on the electronic device to be tested.

8. The test system as claimed in claim 1, wherein the electronic device to be tested is a notebook or a tablet computer that supports a PXE.

9. A test method for an electronic device, comprising:
detecting whether a network connection device having a specific device descriptor is coupled to a universal serial bus (USB) interface of the electronic device during a power on self test (POST), wherein the network connection device comprises a LAN port coupled to a first remote server via a network line;
obtaining a preboot execution environment (PXE) code from the network connection device via the USB interface;
obtaining a specific program from the first remote server via the LAN port of the network connection device according to the PXE code; and
performing a test operation or a preload operation according to the specific program.

10. The test method as claimed in claim 9, further comprising:
storing the PXE code into a memory of the electronic device, wherein the PXE code comprises a PXE ROM code or a PXE unified extensible firmware interface (UEFI) driver.

11. The test method as claimed in claim 10, further comprising:
mapping the PXE ROM code to an expansion area of the memory; and
initializing the PXE UEFI driver.

12. The test method as claimed in claim 10, further comprising:
obtaining boot device information corresponding to the network connection device according to a boot order of a basic input/output system (BIOS).

13. The test method as claimed in claim 12, wherein the step of obtaining the specific program from the first remote server via the LAN port of the network connection device according to the PXE code further comprises:
obtaining the PXE code from the memory when the boot device information indicates that a boot device is set to a PXE boot, and obtaining an operating system (OS) from a second remote server according to the PXE code;
loading a driver corresponding to LAN module of the network connection device to the OS; and
downloading the specific program from the first remote server to a hard disk of the electronic device by the OS.

14. The test method as claimed in claim 12, wherein the step of obtaining the specific program from the first remote server via the LAN port of the network connection device according to the PXE code further comprises:
obtaining an OS from the network connection device via the USB interface according to the PXE code when the boot device information indicates that a boot device is set to a USB device;
loading a driver corresponding to LAN module of the network connection device to the OS; and
downloading the specific program from the first remote server to a hard disk of the electronic device by the OS.

15. The test method as claimed in claim 9, wherein no LAN port is disposed on the electronic device.

16. The test method as claimed in claim 9, wherein the electronic device is a notebook or a tablet computer that supports a PXE.
